(19) United States
(12) Patent Application Publication
(10) Pub. No.: US 2025/0060529 A1
(43) Pub. Date: Feb. 20, 2025

(54) TRI-LAYER CERAMIC OPTICAL FIBERS AND METHOD OF MAKING

(71) Applicant: Government of the United States as represented by the Secretary of the Air Force, Wright-Patterson AFB, OH (US)

(72) Inventors: Hyunjun Kim, Centerville, OH (US); Randall Hay, Beavercreek, OH (US); Kent Averett, Fairborn, OH (US); Cynthia Bowers, Springfield, OH (US); Benjamin Gray, Centerville, OH (US); Brian Sirn, Fairborn, OH (US)

(21) Appl. No.: 18/802,701

(22) Filed: Aug. 13, 2024

Related U.S. Application Data
(60) Provisional application No. 63/519,569, filed on Aug. 15, 2023.
(60) Provisional application No. 63/519,393, filed on Aug. 14, 2023.

(51) Int. Cl. G02B 6/036; C03C 25/106; C03C 25/18; C03C 25/226; C03C 25/42; C23C 14/08; C23C 14/34

(52) U.S. Cl. CPC G02B 6/03694; C03C 25/1061; C03C 25/18; C03C 25/226; C03C 25/42; C23C 14/08; C23C 14/34

(57) ABSTRACT

A tri-layer optical fiber. The fiber has a core which is preferably a single crystal and outer cladding, to reduce signal loss. The cladding process begins with high porosity particles, and is known to introduce porosity in the cladding and at the core/cladding interface. The porosity increases refraction and signal loss. The invention interposes a film layer intermediate the core and cladding. The film layer is sputter coated and preferably of the of same material as the cladding. The film prevents diffusion of the porous cladding into the core, minimizing porosity and improving signal transmission.

### CROSS REFERENCE TO RELATED APPLICATIONS

This application claims priority to and the benefit of provisional application Ser. No. 63/519,393 filed Aug. 14, 2023 and provisional application Ser. No. 63/519,569 filed Aug. 15, 2023, the disclosures of which are incorporated herein by reference.

### STATEMENT OF GOVERNMENT INTEREST

The invention described and claimed herein may be manufactured, licensed and used by and for the Government of the United States of America for all government purposes without the payment of any royalty.

### FIELD OF THE INVENTION

The present invention is related to cladded ceramic optical fibers and more particularly to such single crystal core/poly crystalline cladding optical fibers having an internal mechanism to reduce porosity.

### BACKGROUND OF THE INVENTION

The principle of data transfer through optic fiber cables is based on the phenomenon of total internal reflection. When a light ray moves from a medium of higher refractive index into a medium of lower refractive index, the light ray bends away from the normal. The normal is a perpendicular to the surface boundary of the two media at the point at which the light ray meets the surface boundary.

During optical signal transmission, light is shone along a thin glass fiber and as it hits the glass-air boundary at more than the critical angle it reflects along inside the fiber. A beam of light travels through one or more fibers and as long as the angle of incidence with the walls of a fiber is great enough, the light will be reflected along the fiber with multiple off-axis.

Since the 1950's it has been known that cladding of a fiber urges the optical signals being transmitted to remain confined to the core and not be dissipated when the signal travels a long distance. Cladding is a layer of material with a lower refractive index that covers the core of a fiber optic cable. The core of the fiber optic cable has a higher refractive index than the cladding circumscribing the core. The refractive index of a medium is a ratio between the speed of light in a vacuum to the speed of light in that medium.

Adding cladding increases the critical angle between the core and only those rays that are close to the axis of the fiber pass through. Additionally, with cladding the light rays travel roughly the same distance in the fiber, so that information input at one end of the fiber arrives at the other end with less time dispersion and increased fidelity. And there are fewer reflections along the fiber compared to the distance travelled without cladding, thereby reducing energy loss and the time of transmission.

By confining the light within the core, the cladding helps to minimize signal loss due to leakage of light, thereby maintaining the strength and fidelity of the transmitted signals over long distances. Cladding also provides the benefits of reduced dissipation of the optical signal due to irregularities in the core and overall recued fiber diameter. The cladding also helps to prevent crosstalk between adjacent fibers by confining the light within the core of each fiber. Outside of the cladding may be a jacket for protection against environmental and mechanical hazards.

according to prior art methods, when the ceramic powder that is compacted around a doped single crystal core at elevated temperatures, the single crystal core grows. During that growth, pores are trapped in the grown single crystal area and the dopant diffuses out of the doped core.

However, porosity within either the core or cladding will cause reflection and diffusion of energy. As a crystalline core is grown into the cladding, porosity occurs at the grain boundary between the core and cladding. Again, such porosity is inimical to OPTICAL signal transmission. This situation is particularly acute due to the high porosity of cladding powder, which is typically about 50 percent of the theoretical density.

Accordingly, it is an object of this invention to provide an optical cable having improved signal transmission. More particularly, it is an object of this invention to provide an optical cable having reduced porosity and even more particularly reduced porosity at the grain boundary. Advantageously, the ceramic film of the present invention significantly reduces the size of the resulting pores to be even smaller than the wavelength of light in the fiber minimizing signal loss.

### SUMMARY OF THE INVENTION

In one embodiment the invention comprises an elongate optical fiber. The optical fiber comprises a crystalline core, a ceramic cladding circumscribing the core, and an insulative film intermediate and separating the core and cladding and substantially preventing the grain boundary of the core from growing onto the cladding during a cladding process. The intermediate film may advantageously be amorphous and applied by sputter coating.

In another embodiment the invention comprises a method for making a tri-layer optical fiber comprising. The method comprises the steps of sputter coating crystal particles onto a crystalline core to encase the crystalline core with an insulative film, coextruding the core and film with cladding material to form a tri-layer cladded fiber and sintering the tri-layer cladded fiber to reduce porosity in the cladding. The resulting tri-layer fiber may further be sintered and hot isostatically pressed to reduce porosity of the cladding.

### BRIEF DESCRIPTION OF THE DRAWINGS

FIG. 1 is a schematic perspective view of an exemplary fiber according to the present invention shown partially in cutaway.

FIG. 1A is a table of parameters used to make a fiber as shown in FIG. 1.

FIG. 2 is a SEM photomicrograph of a polished fiber cross-section of the boundary between single crystal fiber core and polycrystalline cladding after coextrusion, drying and sintering according to the prior art.

FIG. 3 is a SEM photomicrograph of the fiber of FIG. 2 according to the prior art with six arrows indicating porosity in the film layer.

FIG. 4 is a SEM photomicrograph of the fiber of FIG. 2 after hot isostatic pressing.

FIG. 5A is a SEM photomicrograph of a polished fiber cross section according to the present invention after drying and sintering.

FIG. 5B is a SEM photomicrograph of a polished fiber cross section according to the present invention after sintering and hot isostatic pressing.

FIG. 6A is a TEM photomicrograph of a polished fiber cross section after sintering and hot isostatic pressing showing a single crystal core/polycrystalline cladding boundary.

FIG. 6B is a TEM photomicrograph with an EDX map of the polished fiber cross section of FIG. 6A.

FIG. 6C is an enlarged view of the EDX photomicrograph of FIG. 6A.

FIG. 7A is a SEM photomicrograph of a sputter coated single crystal YAG core and film before coextrusion.

FIG. 7B is an X-ray diffraction pattern of a sputter coated yttrium aluminum garnet layer, showing the amorphization.

### DETAILED DESCRIPTION OF THE INVENTION

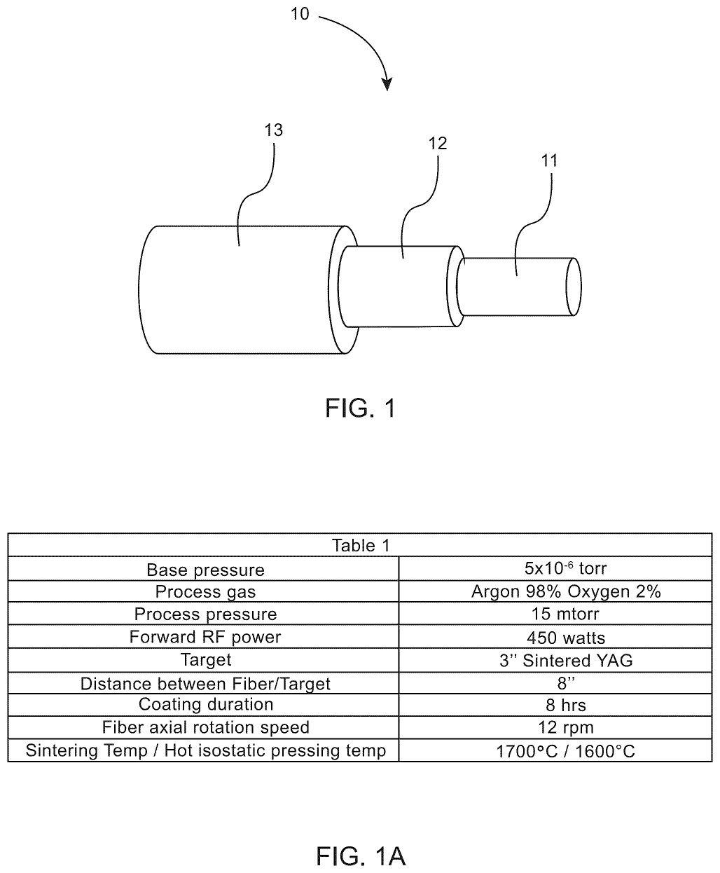

Referring to FIG. 1, in one embodiment the invention comprises an elongate fiber 10 suitable for transmitting optical signals. The fiber 10 comprises a core 11, a cladding 13 circumscribing the core 11 and a film 12 intermediate the core 11 and cladding 13. As described below, a sputter coated ceramic film 12 disposed on a single crystal fiber 10 advantageously and significantly reduces trapped pore size and prevents diffusion of the dopants from the core 11 into the cladding 13. The fiber 10 may have a diameter of 20 microns to 5 mm.

The core 11 is crystalline, and more preferably comprises a single crystal. The core 11 is preferably positively doped to have a greater refractive index than the cladding 13. The cladding 13 is crystalline, preferably polycrystalline. The cladding 13 may be negatively doped in one embodiment. The cladding 13 may optionally be coated with a protective jacket (not shown). The intermediate film 12 may be crystalline and preferably made of the same material as the core 11. If the fiber 10 is to be used as a laser host, the dopant will typically determine the wavelength of the laser.

The sputter coated intermediate film 12 is amorphous. After sputter coating and coextrusion, the inside of the film 12, facing towards and contacting the core 11, becomes single crystalline. The outside of the film 12, facing towards the cladding 13, becomes polycrystalline. The intermediate film 12 may have a thickness of 10 nm to 5000 nm.

The crystalline core 11, intermediate film 12 and outer cladding 13 may be made of ceramic material, and more particularly sapphire, yttrium oxide, and/or preferably yttrium aluminum garnet (YAG). The film 12 is described as an insulative film 12, meaning that diffusion of cladding 13 particles into the core 11 is substantially and prophylactically blocked, thereby reducing porosity and improving signal transmission. The crystalline core 11, intermediate film 12 and outer cladding 13 each may be made of any one of these materials. More preferably the core 11, film 12 and cladding 13 are made of mutually identical materials.

According to one aspect of the present invention, prior to applying a polycrystalline cladding 13 onto the doped single crystal core 11 fiber 10, the core 11 fiber 10 is sputter coated with an undoped material. The sputter coat material is preferably identical to the core 11 material. During sputtering, the core 11 may be axially rotated to provide for an even coating thickness around the core 11. After coating, processes for cladding 13 and particularly polycrystalline cladding 13 may begin in known fashion.

Sputter coating is a physical vapor deposition (PVD) process used to apply a very thin, functional coating on a substrate. The process involves bombarding a target material with energetic ions, causing atoms to dis lodge and depos it onto a substrate, forming a thin film 12. The process starts by electrically charging a sputtering cathode which in turn forms a plasma causing material to be ejected from the target surface. At a molecular level the target material is directed at the substrate through a momentum transfer process. The high energy target material impacts the substrate and is driven into the surface of the substrate forming a very strong bond at an atomic level. Other prophetically suitable methods of PVD include magnetron, vacuum, radio frequency and reactive sputtering.

This material is now a permanent part of the substrate rather than an applied coating or plating of the surface. A benefit of sputter coating is that a stable plasma is created which, in turn, provides a consistent, uniform deposition of a film 12.

The sputter coated film 12 is intermediate the core 11 and green cladding 13. The sputter coated film 12 provides a diffusion barrier. During heat treatment such as sintering and hot isostatic pressing, the film 12 becomes a single core 11 due to the core 11 acting as a seed for single crystal growing and polycrystalline on the cladding 13 side of the film 12. The single crystal acts as a diffusion barrier, preventing diffusion from the core 11 to the cladding 13 due to the diffusivity of a single crystal being less than the diffusivity of a polycrystalline material. Generally the grain boundaries of a polycrystalline material provide diffusivity paths, increasing overall diffusivity.

The sputter coated film 12 also reduces porosity in the cladding 13. Without the sputter coated film 12 the cladding 13 powder would be in direct contact with the core 11 which would act as a seed for growing the single crystal of the core 11 into the powder compact of the cladding 13. Because the powder is porous the pores are trapped in the grown single crystal layer of cladding 13.

The sputter coated film 12 has a greater density than the powder compact of the cladding 13. When the sputter coated film 12 converts from being amorphous to single crystal the volume shrinks and generates pores. But the pores generated by this conversion are less than the pores generated by direct contact of the cladding 13 with a core 11, due to the greater density of the sputter coated film 12 than the green cladding 13.

Referring to FIG. 1A, in one nonlimiting example a fiber 10 was produced according to the present invention and the parameters in Table 1. The fiber 10 had a Yb: YAG core 11 which was sputter coated with undoped YAG to form a film 12 around the core 11. The core 11/film 12 precursor was then coextruded with an undoped YAG to form the exterior cladding 13. After cladding 13 the resulting fiber 10 was then sintered and hot isostatically pressed (HIP) to improve cladding 13. It was found that the Yb (ytterbium) dopant did not diffuse into the cladding 13, significantly reducing the size of trapped pores.

After forming the tri-layer fiber 10, the fiber 10 was processed as follows. Organic (binder) was removed by heating the fiber 10 from room temperature to 600° C. for 6 to 18 hours in oxygen or air, then soaking at 600° C. for 30 minutes. The fiber 10 was then sintered by heating to 1650-1700° C. with a heating rate of 5-15° C./min, soaking for 2-10 hrs and cooling to room temperature with the cooling rate of 10-40° C./min. Sintering may be done under vacuum or an oxygen atmosphere. HIP was performed by heating and cooling the fiber 10 at 10° C./min. and soaking at 1600° C. for 5 hours under 30 ksi argon.

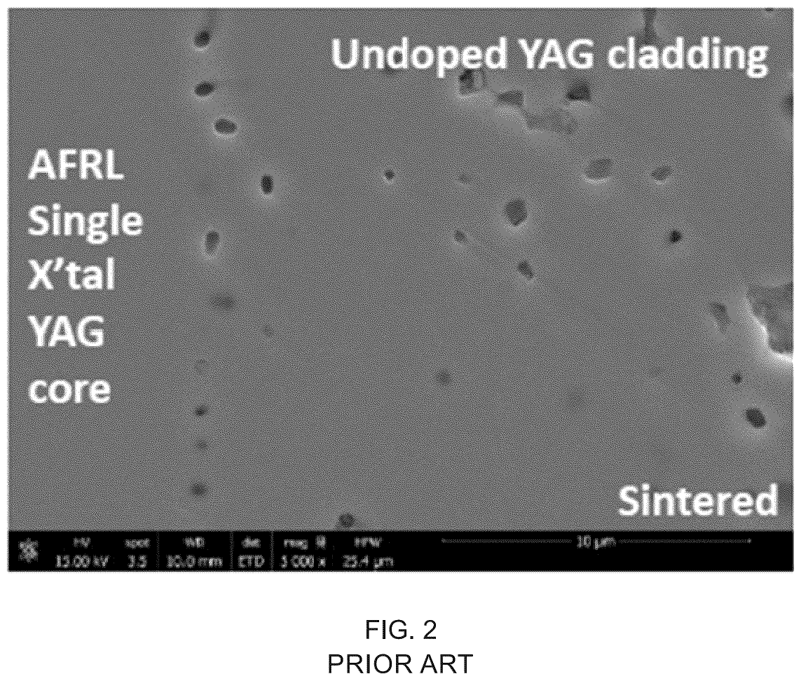

Referring to FIG. 2, a SEM of a fiber 10 according to the prior art is shown. This fiber 10 shows the deleterious porosity in the cladding 13.

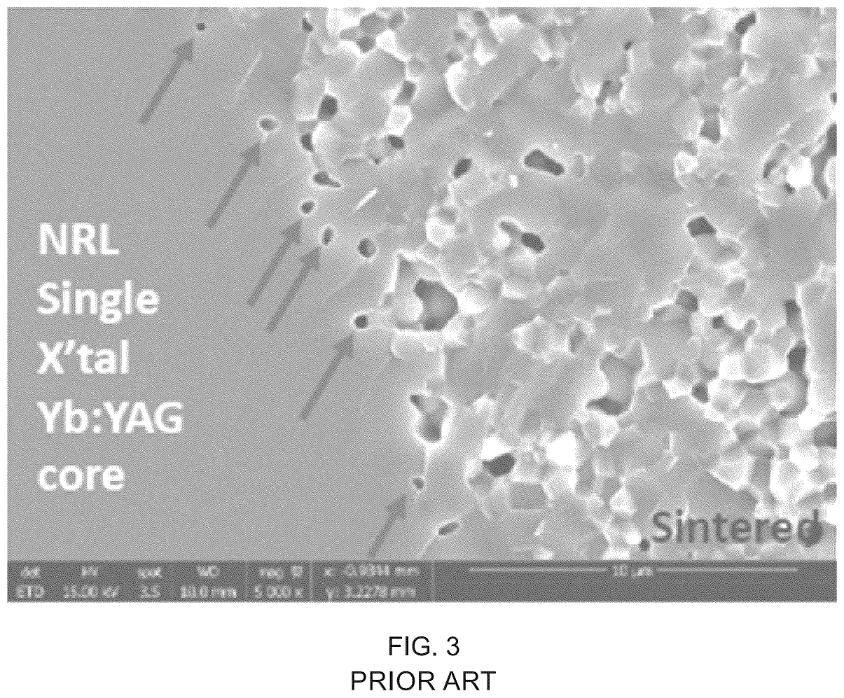

Referring to FIG. 3, the fiber 10 is shown fractured, distinguishing the single crystal core 11 and polycrystalline cladding 13. Crack propagation modes in single crystal and polycrystalline area are different. During sintering, the single crystal core 11 grows into the polycrystalline cladding 13 area. During growing, pores are trapped in the single crystal area as designed by the arrows. The pores designed by the arrows cannot be removed with HIP because pores in a single area are usually very stable.

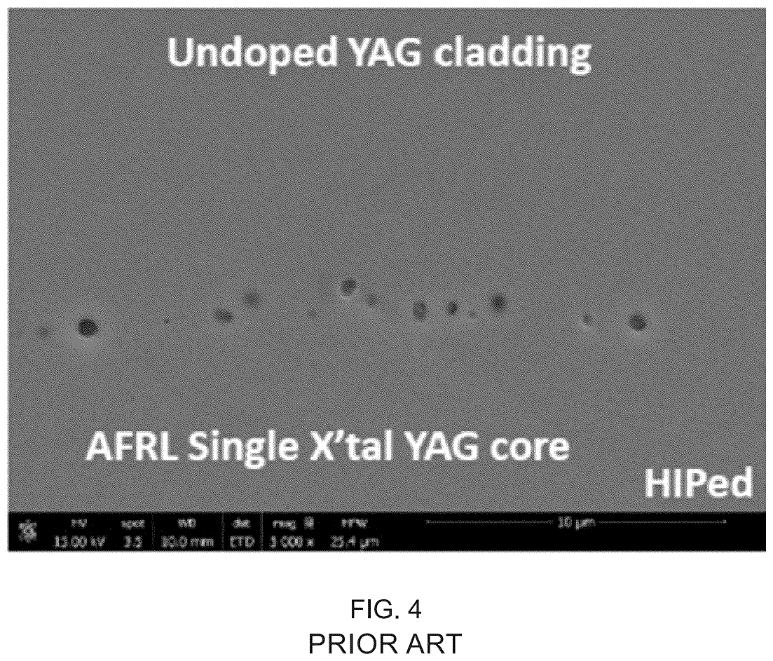

Referring to FIG. 4, a SEM of a fiber 10 according to the prior art is shown. The polished cross-section shows that after sintering and HIP, the HIP operation removed pores in the polycrystalline cladding 13 area. But the pores trapped in the single crystal core 11 remain even after HIP.

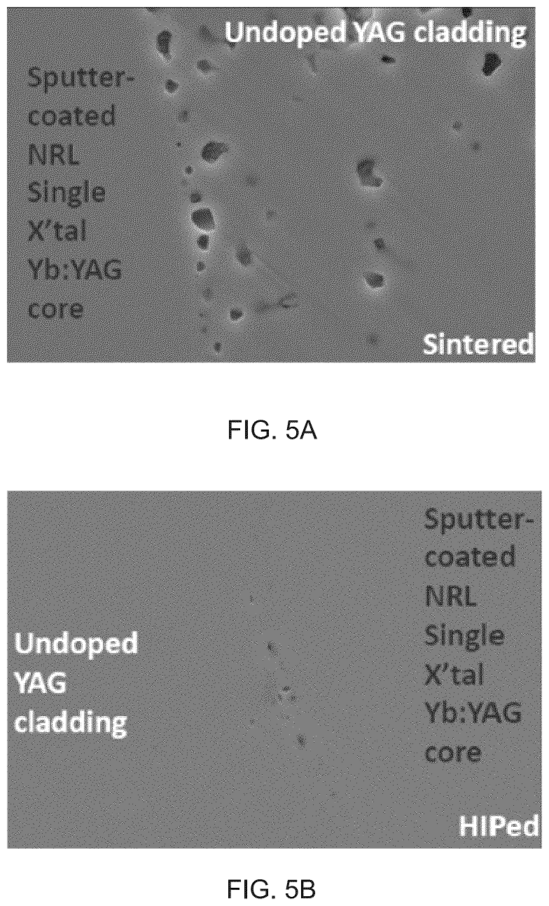

Referring to FIG. 5A a sintered fiber 10 according to the present invention is shown. This fiber 10 exhibits significant porosity in the cladding 13 which can be mitigated with HIP.

Referring to FIG. 5B, a fiber 10 of the type of FIG. 5A is shown. This fiber 10 was sputter coated with YAG particles before coextrusion, unexpectedly and advantageously reducing the size of residual pores. As described above, upon heating, the particles form a continuous, insulative film 12. This fiber 10 has been subjected to sintering and HIP, advantageously reducing deleterious porosity.

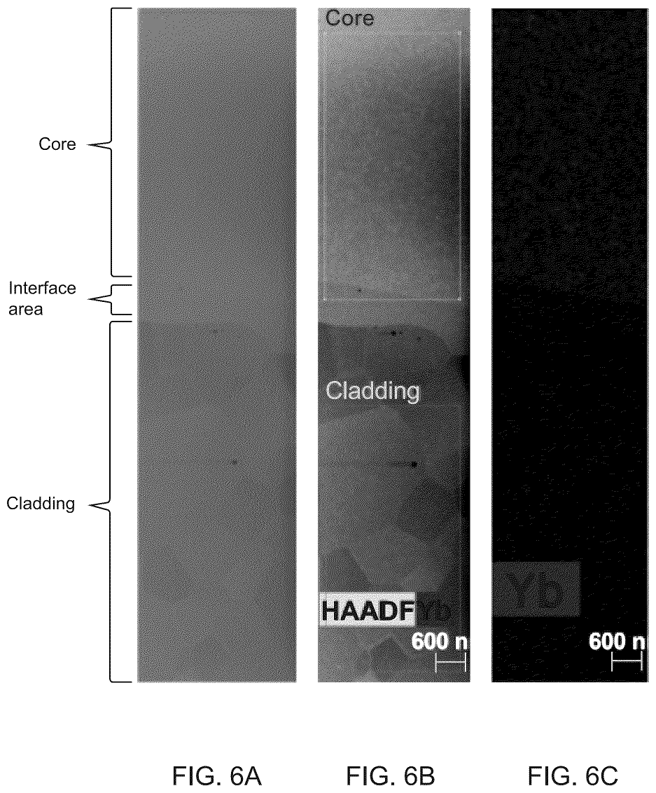

Referring to FIG. 6A, FIG. 6B and FIG. 6C, a fiber 10 is shown that was sputter coated with a YAG particles, then coextruded to form the cladding 13. As described above, upon heating the particles form a continuous, insulative film 12. FIG. 6A shows the TEM image proximate the core 11-cladding 13 boundary. The interface at the core 11 and cladding 13 area is a single crystal and formed from the amorphous sputter coated YAG layer. During heating, the sputter coated YAG layer transformed to an undoped single crystal YAG film 12. The film 12 layer is approximately 1.5 microns thick.

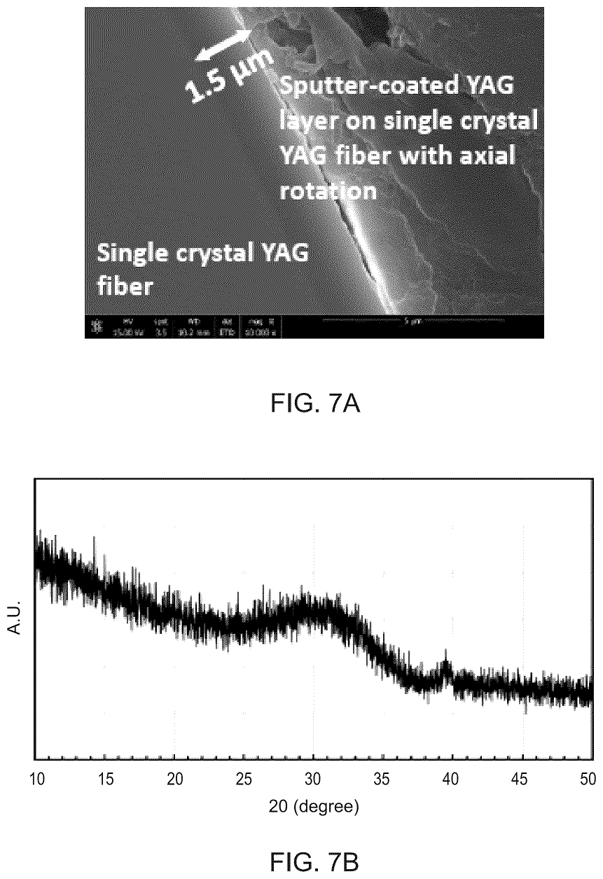

FIG. 6B and FIG. 6C. show an energy dispersive X-ray (EDX) map of Yb. EDX may be used to identify elements by a respective Z-number. The Yb is shown not to diffuse out of the core 11 because the film 12 acted as a prophylactic, insulative barrier against Yb diffusion. FIG. 6B and FIG. 7B particularly show the film 12 is advantageously amorphous.

FIG. 7A Is an X-ray diffraction (XRD) of a sputter coated YAG film 12. The XRD shows the YAG film 12 is amorphous as applied by the sputter coating.

All values disclosed herein are not strictly limited to the exact numerical values recited. Unless otherwise specified, each such dimension is intended to mean both the recited value and a functionally equivalent range surrounding that value. For example, a dimension disclosed as “40 mm” is intended to mean “about 40 mm.” The term “or” as used herein is to be interpreted as an inclusive or meaning any one or any combination. Therefore, “A, B or C” means “any of the following: A; B; C; A and B; A and C; B and C; A, B and C.” Every document cited herein, including any cross referenced or related patent or application, is hereby incorporated herein by reference in its entirety unless expressly excluded or otherwise limited. The citation of any document or commercially available component is not an admission that such document or component is prior art with respect to any invention disclosed or claimed herein or that alone, or in any combination with any other document or component, teaches, suggests or discloses any such invention. Further, to the extent that any meaning or definition of a term in this document conflicts with any meaning or definition of the same term in a document incorporated by reference, the meaning or definition assigned to that term in this document shall govern according to Phillips v. AWH Corp., 415 F.3d 1303 (Fed. Cir. 2005). All limits shown herein as defining a range may be used with any other limit defining a range of that same parameter. That is the upper limit of one range may be used with the lower limit of another range for the same parameter, and vice versa. As used herein, when two components are joined or connected the components may be interchangeably contiguously joined together or connected with an intervening element therebetween. A component joined to the distal end of another component may be juxtaposed with or joined at the distal end thereof. While particular embodiments of the present invention have been illustrated and described, it would be obvious to those skilled in the art that various other changes and modifications can be made without departing from the spirit and scope of the invention and that various embodiments described herein may be used in any combination or combinations. It is therefore intended the appended claims cover all such changes and modifications that are within the scope of this invention.

What is claimed is:

1. An optical fiber comprising:
a crystalline core;
a ceramic cladding circumscribing the core;
an insulative film intermediate and separating the core and cladding and substantially preventing the grain boundary of the core from growing onto the cladding during a cladding process.

2. A fiber according to claim 1 wherein the film is a sputter coated film.

3. A fiber according to claim 2 wherein the film is a ceramic film.

4. A fiber according to claim 3 wherein the film is a YAG film.

5. A fiber according to claim 4 wherein the film has a thickness of 10 nm to 5000 nm.

6. A fiber according to claim 4 having a diameter of 20 microns to 5 mm

7. An optical fiber comprising:
a positively doped crystalline core;
a ceramic cladding circumscribing the core;
a film intermediate and separating the core and cladding and substantially preventing the grain boundary of the core from growing onto the cladding during a cladding process.

8. A fiber according to claim 7 wherein the core comprises YAG crystalline material.

9. A fiber according to claim 8 wherein the core comprises a single YAG crystal.

10. A fiber according to claim 9 wherein the film comprises amorphous YAG.

11. A fiber according to claim 10 wherein the cladding comprises YAG.

12. A fiber according to claim 11 wherein the cladding comprises polycrystalline YAG.

13. A fiber according to claim 7 wherein the core, film and cladding comprise a mutually identical material.

14. A method for making a tri-layer optical fiber comprising, in order, the steps of:
sputter coating crystal particles onto a crystalline core to encase the crystalline core with an insulative film;
coextruding the core and film with cladding material to form a tri-layer cladded fiber; and
sintering the tri-layer cladded fiber to reduce porosity in the cladding.

15. A method according to claim 14 furthering comprising the step of hot isostatically pressing the tri-layer fiber to further reduce porosity of the cladding.

16. A method according to claim 15 wherein the step of sputter coating an insulative film comprises the step of sputter coating an amorphous insulative film.

17. A method according to claim 16 wherein the step of sputter coating the crystal particles to form an insulative film on the crystalline core comprises cathode sputter coating.

18. A method according to claim 17 wherein the film has a thickness ranging from of 10 nm to 5000 nm.

19. A method according to claim 18 wherein the core comprises a single YAG crystal.

20. A method according to claim 19 wherein the core, particles and cladding comprise a mutually identical YAG material.
